(19) United States
(12) Patent Application Publication
(10) Pub. No.: US 2024/0113686 A1
(43) Pub. Date: Apr. 4, 2024

(54) ACOUSTIC WAVE DEVICE

(71) Applicant: Murata Manufacturing Co., Ltd., Nagaokakyo-shi (JP)

(72) Inventor: Tetsuya KIMURA, Nagaokakyo-shi (JP)

(21) Appl. No.: 18/528,843

(22) Filed: Dec. 5, 2023

Related U.S. Application Data
(63) Continuation of application No. PCT/JP2022/024183, filed on Jun. 16, 2022.
(60) Provisional application No. 63/211,590, filed on Jun. 17, 2021.

(51) Int. Cl. H03H 9/17; H03H 9/13

(52) U.S. Cl. CPC H03H 9/176; H03H 9/13

(57) ABSTRACT

An acoustic wave device includes a support substrate with a thickness in a first direction, an intermediate layer on the support substrate, a piezoelectric layer on the intermediate layer, and an IDT electrode including a first electrode finger at the piezoelectric layer in the first direction and extending in a second direction intersecting the first direction, a first busbar electrode connected to the first electrode finger, a second electrode finger facing the first electrode finger in a third direction orthogonal or substantially orthogonal to the second direction and extending in the second direction, and a second busbar electrode connected to the second electrode finger. The intermediate layer includes a void portion at least partially overlapping the IDT electrode in plan view, and a surface roughness of an inner sidewall of the intermediate layer is about 0.0055 μm or more.

### CROSS REFERENCE TO RELATED APPLICATIONS

This application claims the benefit of priority to Provisional Application No. 63/211,590 filed on Jun. 17, 2021 and is a Continuation application of PCT Application No. PCT/JP2022/024183 filed on Jun. 16, 2022. The entire contents of each application are hereby incorporated herein by reference.

### BACKGROUND OF THE INVENTION

### 1. Field of the Invention

The present disclosure relates to acoustic wave devices.

### 2. Description of the Related Art

Japanese Unexamined Patent Application Publication No. 2012-257019 describes an acoustic wave device.

In the acoustic wave device described in Japanese Unexamined Patent Application Publication No. 2012-257019, frequency characteristics may deteriorate due to a large spurious emission in a pass band.

### SUMMARY OF THE INVENTION

Example embodiments of the present invention provide acoustic wave devices each with a reduced spurious emission in a pass band.

An acoustic wave device according to an example embodiment of the present invention includes a support substrate with a thickness in a first direction, an intermediate layer on the support substrate, a piezoelectric layer on the intermediate layer, and an IDT electrode including a first electrode finger at the piezoelectric layer in the first direction and extending in a second direction intersecting the first direction, a first busbar electrode to which the first electrode finger is connected, a second electrode finger facing the first electrode finger in a third direction orthogonal or substantially orthogonal to the second direction and extending in the second direction, and a second busbar electrode to which the second electrode finger is connected. The intermediate layer includes a void portion at least partially overlapping the IDT electrode in plan view, and a surface roughness of an inner sidewall of the intermediate layer is about 0.0055 μm or more.

According to example embodiments of the present invention, a spurious emission in a pass band is reduced.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1A is a perspective view illustrating an acoustic wave device according to a first example embodiment of the present invention.

FIG. 1B is a plan view illustrating an electrode structure of the first example embodiment of the present invention.

FIG. 2 is a sectional view of a portion taken along line II-II in FIG. 1A.

FIG. 3A is a schematic sectional view illustrating Lamb waves propagating in a piezoelectric layer of a comparative example.

FIG. 3B is a schematic sectional view illustrating bulk waves of the first-order thickness-shear mode propagating in a piezoelectric layer of the first example embodiment of the present invention.

FIG. 4 is a schematic sectional view illustrating the direction of the amplitude of bulk waves of the first-order thickness-shear mode propagating in the piezoelectric layer of the first example embodiment of the present invention.

FIG. 5 is an explanatory diagram illustrating an example of resonance characteristics of the acoustic wave device of the first example embodiment of the present invention.

FIG. 6 is an explanatory diagram illustrating the relationship between d/2p and a fractional bandwidth as a resonator in the acoustic wave device of the first example embodiment of the present invention when p is the center-to-center distance of adjacent electrodes or the average distance of the center-to-center distances of adjacent electrodes and d is the average thickness of the piezoelectric layer.

FIG. 7 is a plan view illustrating an example where a single pair of electrodes is provided in the acoustic wave device of the first example embodiment of the present invention.

FIG. 8 is a reference diagram illustrating an example of resonance characteristics of the acoustic wave device of the first example embodiment of the present invention.

FIG. 9 is an explanatory diagram illustrating the relationship, in the acoustic wave device of the first example embodiment of the present invention, between a fractional bandwidth in a case where a large number of acoustic wave resonators are configured and the amount of phase rotation of spurious impedance normalized by about 180° as spurious size.

FIG. 10 is an explanatory diagram illustrating the relationship between d/2p, a metallization ratio MR, and a fractional bandwidth.

FIG. 11 is an explanatory diagram illustrating a map of a fractional bandwidth in relation to the Euler angles (0°, θ, ψ) of LiNbO₃ in a case where d/p is almost zero.

FIG. 12 is a partially cut-away perspective view illustrating an acoustic wave device according to an example embodiment of the present invention.

FIG. 13 is a sectional view illustrating an acoustic wave device according to an example embodiment of the present invention.

FIG. 14 is a perspective view illustrating an example of the acoustic wave device according to the first example embodiment of the present invention.

FIG. 15 is a sectional view taken along line XV-XV in FIG. 14.

FIG. 16 is a diagram illustrating the impedance characteristics of acoustic wave devices according to Test Examples 1 to 4.

FIG. 17 is a diagram illustrating the return loss of the acoustic wave device according to Test Example 1.

FIG. 18 is a diagram illustrating the return loss of the acoustic wave device according to Test Example 2.

FIG. 19 is a diagram illustrating the return loss of the acoustic wave device according to Test Example 3.

FIG. 20 is a diagram illustrating the return loss of the acoustic wave device according to Test Example 4.

FIG. 21 is a diagram illustrating the peak-to-valley ratio of ripples in the acoustic wave devices according to Test Examples 1 to 4.

### DETAILED DESCRIPTION OF THE EXAMPLE EMBODIMENTS

Example embodiments of the present invention are described in detail below with reference to the drawings. The present invention is not limited by the example embodiments. The example embodiments described in the present disclosure are merely exemplary, and in and after a second example embodiment and modifications in which the configurations of different example embodiments are partially replaceable or combinable, descriptions of matters common to the first example embodiment are omitted, and only differences from the first example embodiment are described. Specifically, operations and advantageous effects of the same or corresponding configurations are not described in every example embodiment.

### First Example Embodiment

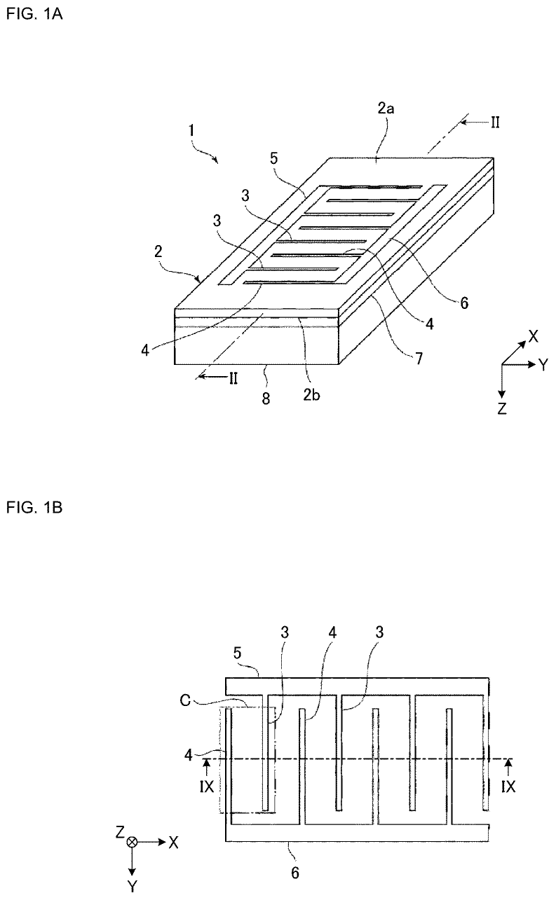

FIG. 1A is a perspective view illustrating an acoustic wave device according to a first example embodiment of the present invention. FIG. 1B is a plan view illustrating the electrode structure of the first example embodiment.

An acoustic wave device 1 of the first example embodiment includes a piezoelectric layer 2 made of, for example, LiNbO₃. The piezoelectric layer 2 may be made of, for example, LiTaO₃. The cut-angle of LiNbO₃ or LiTaO₃ is, in the first example embodiment, Z-cut, for example. The cut-angle of LiNbO₃ or LiTaO₃ may be, for example, rotated Y-cut or may be X-cut. The propagation orientation is preferably, for example, ±about 30° of Y-propagation and X-propagation.

The thickness of the piezoelectric layer 2 is not limited to a particular thickness, but in order to effectively excite the first-order thickness shear mode, the thickness of the piezoelectric layer 2 is preferably, for example, about 50 nm or more and about 1000 nm or less.

The piezoelectric layer 2 includes a first main surface 2a and a second main surface 2b facing each other in the Z-direction. Electrode fingers 3 and electrode fingers 4 are provided on the first main surface 2a.

The electrode fingers 3 are an example of the “first electrode finger,” and the electrode fingers 4 are an example of the “second electrode finger”. In FIGS. 1A and 1B, the plurality of electrode fingers 3 are a plurality of “first electrodes” connected to a first busbar electrode 5. The plurality of electrode fingers 4 are a plurality of “second electrodes” connected to a second busbar electrode 6. The plurality of electrode fingers 3 and the plurality of electrode fingers 4 are interdigitated with each other. An interdigital transducer (IDT) electrode including the electrode fingers 3, the electrode fingers 4, the first busbar electrode 5, and the second busbar electrode 6 is thus provided.

The electrode fingers 3 and the electrode fingers 4 each have a rectangular or substantially rectangular shape and a lengthwise direction. In a direction orthogonal or substantially orthogonal to the lengthwise direction, the electrode fingers 3 and the electrode fingers 4 adjacent to the electrode fingers 3 face each other. The lengthwise direction of the electrode fingers 3 and the electrode fingers 4 and the direction orthogonal or substantially orthogonal to the lengthwise direction of the electrode fingers 3 and the electrode fingers 4 are both directions intersecting a thickness direction of the piezoelectric layer 2. Thus, it can also be said that the electrode fingers 3 and the electrode fingers 4 adjacent to the electrode fingers 3 face each other in a direction intersecting the thickness direction of the piezoelectric layer 2. In the descriptions below, the thickness direction of the piezoelectric layer 2 may be referred to as a Z-direction (or a first direction), the lengthwise direction of the electrode fingers 3 and the electrode fingers 4 may be referred to as a Y-direction (or a second direction), and the direction orthogonal to the lengthwise direction of the electrode fingers 3 and the electrode fingers 4 may be referred to as an X-direction (or a third direction).

Also, the lengthwise direction of the electrode fingers 3 and the electrode fingers 4 may be interchanged with the direction orthogonal or substantially orthogonal to the lengthwise direction of the electrode fingers 3 and the electrode fingers 4 illustrated in FIGS. 1A and 1B. In other words, the electrode fingers 3 and the electrode fingers 4 may extend in the direction in which the first busbar electrode 5 and the second busbar electrode 6 extend in FIGS. 1A and 1B. In this case, the first busbar electrode 5 and the second busbar electrode 6 extend in the direction in which the electrode fingers 3 and the electrode fingers 4 extend in FIGS. 1A and 1B. A plurality of pairs each being a pair of the electrode finger 3 connected to one potential and the electrode finger 4 connected to the other potential are arranged in the direction orthogonal or substantially orthogonal to the lengthwise direction of the electrode fingers 3 and the electrode fingers 4 described above.

A state where the electrode finger 3 and the electrode finger 4 are adjacent to each other refers not to a state where the electrode finger 3 and the electrode finger 4 are arranged in direct contact with each other, but to a state where the electrode finger 3 and the electrode finger 4 are arranged with spacing interposed therebetween. Also, in a case where the electrode finger 3 and the electrode finger 4 are adjacent to each other, electrodes connected to a hot electrode or a ground electrode, including other electrode fingers 3 and electrode fingers 4, are not disposed between the electrode finger 3 and the electrode finger 4. The number of these pairs does not need to be an integer, and there may be 1.5 pairs, 2.5 pairs, and the like.

The center-to-center distance, i.e., the pitch, between the electrode finger 3 and the electrode finger 4 is preferably, for example, in the range from about 1 μm or more to about 10 μm or less. The center-to-center distance between the electrode finger 3 and the electrode finger 4 is the distance between the widthwise center of the electrode finger 3 in the direction orthogonal to the lengthwise direction of the electrode finger 3 and the widthwise center of the electrode finger 4 in the direction orthogonal or substantially orthogonal to the lengthwise direction of the electrode finger 4.

Further, in a case where at least one of the electrode finger 3 and the electrode finger 4 includes a plurality of electrode fingers (in a case where there are 1.5 electrode pairs or more when an electrode pair is formed by the electrode finger 3 and the electrode finger 4), the center-to-center distance between the electrode finger 3 and the electrode finger 4 refers to the average value of the center-to-center distances between respective adjacent electrode fingers of the 1.5 pairs or more of the electrode finger 3 and the electrode finger 4.

Also, the width of the electrode fingers 3 and the electrode fingers 4, i.e., the dimension of the electrode fingers 3 and the electrode fingers 4 measured in the direction in which the electrode fingers 3 and the electrode fingers 4 face each other is preferably, for example, in the range from about 150 nm or more to about 1000 nm or less. The center-to-center distance between the electrode finger 3 and the electrode finger 4 is the distance between the center of a dimension of the electrode finger 3 measured in the direction (the width dimension) orthogonal or substantially orthogonal to the lengthwise direction of the electrode finger 3 and the center of a dimension of the electrode finger 4 measured in the direction (the width dimension) orthogonal or substantially orthogonal to the lengthwise direction of the electrode finger 4.

Because a Z-cut piezoelectric layer is used in the first example embodiment, the direction orthogonal or substantially orthogonal to the lengthwise direction of the electrode fingers 3 and the electrode fingers 4 is the direction orthogonal or substantially orthogonal to the polarization direction of the piezoelectric layer 2. This does not apply if a piezoelectric body of a different cut-angle is used as the piezoelectric layer 2. Herein, being “orthogonal” is not limited to being strictly orthogonal and may mean substantially orthogonal (for example, an angle between the polarization direction and the direction orthogonal to the lengthwise direction of the electrode fingers 3 and the electrode fingers 4 is about 90°±10°).

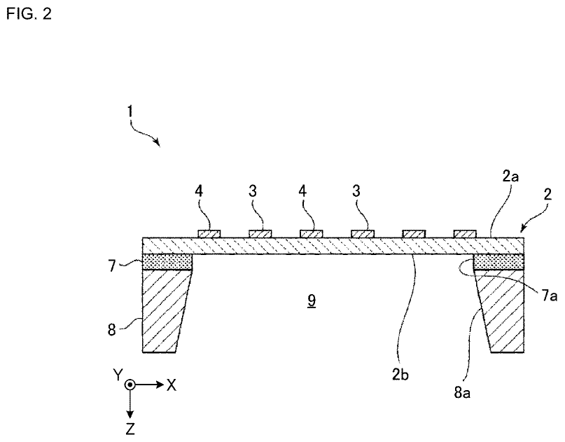

A support substrate 8 is laminated on the second main surface 2b side of the piezoelectric layer 2 with an intermediate layer 7 interposed therebetween. The intermediate layer 7 and the support substrate 8 have frame shapes and include cavities 7a, 8a as illustrated in FIG. 2, thus providing a void portion (an air gap) 9.

The void portion 9 is provided so as not to hinder vibrations of the piezoelectric layer 2 in an excitation region C. Thus, the support substrate 8 is laminated on the second main surface 2b with the intermediate layer 7 interposed therebetween, at a position where the support substrate 8 does not overlap a portion where at least one pair of the electrode finger 3 and the electrode finger 4 is provided. The intermediate layer 7 does not have to be provided. Thus, the support substrate 8 may be laminated on the second main surface 2b of the piezoelectric layer 2 directly or indirectly.

The intermediate layer 7 is made of, for example, silicon oxide, although the intermediate layer 7 can be made of an appropriate insulating material different from silicon oxide, such as, for example, silicon nitride or alumina.

The support substrate 8 is made of, for example, Si. The plane orientation of Si at the plane at the piezoelectric layer 2 side may be (100) or (110) or may be (111). Preferably, Si has a high resistivity of, for example, about 4 kΩ or more, although the support substrate 8 can also be made using an appropriate insulating material or semiconductor material. Examples of a material usable as the support substrate 8 include piezoelectric bodies such as aluminum oxide, lithium tantalate, lithium niobate, and crystals, various kinds of ceramics such as alumina, magnesia, sapphire, silicon nitride, aluminum nitride, silicon carbide, zirconia, cordierite, mullite, steatite, and forsterite, dielectrics such as diamond and glass, semiconductors such as gallium nitride.

The pluralities of electrode fingers 3 and electrode fingers 4, the first busbar electrode 5, and the second busbar electrode 6 are each made of an appropriate metal or metal alloy, such as, for example, Al or an AlCu alloy. In the first example embodiment, the electrode fingers 3, the electrode fingers 4, the first busbar electrode 5, and the second busbar electrode 6 include, for example, an Al film laminated on a Ti film. An adhesion layer other than a Ti film may also be used.

For driving, an alternating current voltage is applied between the plurality of electrode fingers 3 and the plurality of electrode fingers 4. More specifically, an alternating current voltage is applied between the first busbar electrode 5 and the second busbar electrode 6. This makes it possible to obtain resonance characteristics utilizing bulk waves of the first-order thickness-shear mode excided at the piezoelectric layer 2.

Also, in the acoustic wave device 1, d/p is, for example, about 0.5 or less where d is the thickness of the piezoelectric layer 2, and p is the center-to-center distance between the electrode finger 3 and the electrode finger 4 adjacent to each other among the plurality of pairs of the electrode finger 3 and the electrode finger 4. Thus, the above-described bulk waves of the first-order thickness-shear mode are effectively excited, making it possible to obtain good resonance characteristics. More preferably, for example, d/p is about 0.24 or less, and in this case, even better resonance characteristics can be obtained.

In a case where at least one of the electrode finger 3 and the electrode finger 4 includes a plurality of electrode fingers as in the first example embodiment, i.e., in a case where there are 1.5 pairs or more of the electrode finger 3 and the electrode finger 4 when an electrode pair is defined by the electrode finger 3 and the electrode finger 4, the center-to-center distance p between the electrode finger 3 and the electrode finger 4 adjacent to each other is the average value of the center-to-center distances between respective adjacent electrode fingers of the electrode finger 3 and the electrode finger 4.

In the acoustic wave device 1 of the first example embodiment having the configuration described above, it is less likely that the Q factor is decreased even if the number of pairs of the electrode finger 3 and the electrode finger 4 is reduced so as to reduce the size of the device. This is because the resonator does not require reflectors on both sides and therefore experiences less propagation loss. The resonator does not require the reflectors because bulk waves of the first-order thickness-shear mode are used.

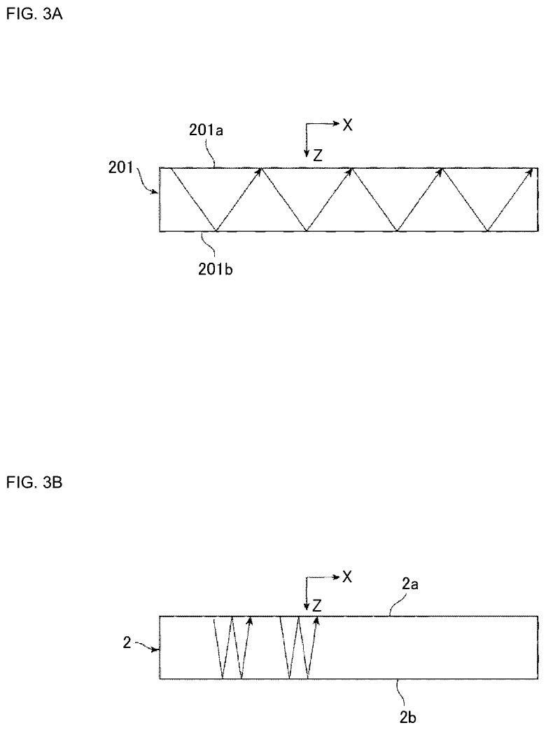

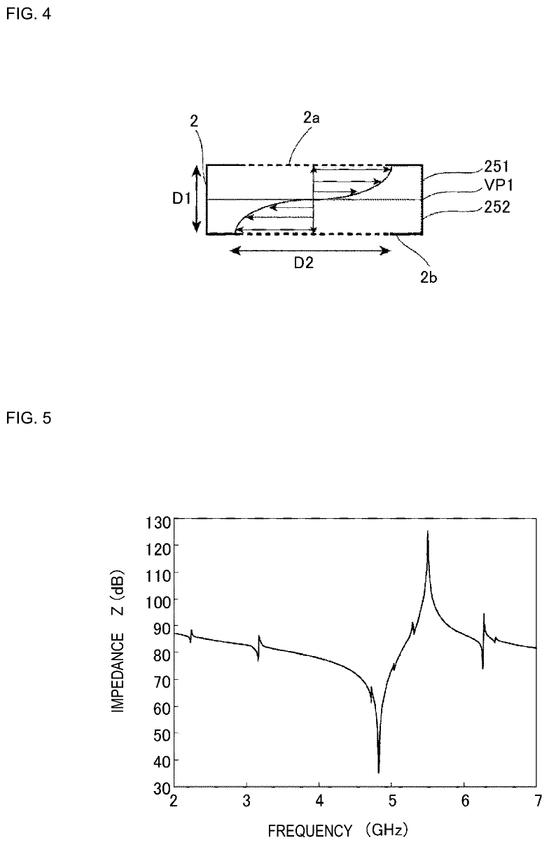

FIG. 3A is a schematic sectional view illustrating Lamb waves propagating in a piezoelectric layer of a comparative example. FIG. 3B is a schematic sectional view illustrating bulk waves of the first-order thickness-shear mode propagating in the piezoelectric layer of the first example embodiment. FIG. 4 is a schematic sectional view illustrating the direction of the amplitude of bulk waves of the first-order thickness-shear mode propagating in the piezoelectric layer of the first example embodiment.

FIG. 3A shows an acoustic wave device similar to the one described in Japanese Unexamined Patent Application Publication No. 2012-257019, and Lamb waves propagate in the piezoelectric layer. As illustrated in FIG. 3A, waves propagate in a piezoelectric layer 201 as indicated by the arrows. The piezoelectric layer 201 includes a first main surface 201a and a second main surface 201b, and a thickness direction connecting the first main surface 201a and the second main surface 201b is the Z-direction. The X-direction is a direction in which the electrode fingers 3, 4 of the IDT electrode are arranged. As illustrated in FIG. 3A, Lamb waves propagate in the X-direction as shown in the diagram. The entire piezoelectric layer 201 vibrates because the waves are plate waves. However, because the waves propagate in the X-direction, reflectors are provided at both sides to obtain resonance characteristics. For this reason, the waves experience propagation loss, and the Q factor decreases when an attempt to reduce the size of the device, i.e., when the number of pairs of the electrode fingers 3, 4 are reduced.

In contrast, in the acoustic wave device of the first example embodiment, as illustrated in FIG. 3B, vibration displacement is in the thickness-shear direction, and thus, the waves propagate almost in the direction of a line connecting the first main surface 2a and the second main surface 2b of the piezoelectric layer 2, i.e., in the Z-direction, and resonate. In other words, the X-direction component of the waves is significantly smaller than the Z-direction component. Also, because resonance characteristics are obtained due to this propagation of the waves in the Z-direction, reflectors are not required. Thus, propagation loss which would otherwise occur in propagation to the reflectors does not occur. Thus, it is less likely that the Q factor decreases even if the number of electrode pairs of the electrode finger 3 and the electrode finger 4 is reduced so as to reduce device size.

The direction of the amplitude of the bulk waves of the first-order thickness-shear mode is, as illustrated in FIG. 4, opposite between a first region 251 included in the excitation region C (see FIG. 1B) in the piezoelectric layer 2 and a second region 252 included in the excitation region C. FIG. 4 schematically illustrates bulk waves in a case where a voltage is applied between the electrode fingers 3 and the electrode fingers 4 so that the electrode fingers 4 are at a higher potential than the electrode fingers 3. The first region 251 is a region, in the excitation region C, between the first main surface 2a and a virtual plane VP1 which is orthogonal to the thickness direction of the piezoelectric layer 2 and bisects the piezoelectric layer 2. The second region 252 is a region, in the excitation region C, between the virtual plane VP1 and the second main surface 2b.

In the acoustic wave device 1, at least one pair of the electrode finger 3 and the electrode finger 4 is provided. Because waves do not propagate in the X-direction, a plurality of electrode pairs of the electrode finger 3 and the electrode finger 4 are not necessarily provided. Thus, it is sufficient if at least one electrode pair is provided.

For example, the electrode finger 3 is an electrode connected to the hot potential, and the electrode finger 4 is an electrode connected to the ground potential, although the electrode finger 3 may be connected to the ground potential and the electrode finger 4 may be connected to the hot potential instead. In the first example embodiment, at least one pair of electrodes is, as described above, an electrode connected to the hot potential or an electrode connected to the ground potential, and no floating electrode is provided.

FIG. 5 is an explanatory diagram illustrating an example of the resonance characteristics of the acoustic wave device of the first example embodiment. Design parameters for the acoustic wave device 1 achieving the resonance characteristics illustrated in FIG. 5 are as follows.
The piezoelectric layer 2: LiNbO₃ with Euler angles (0°, 0°, 90°)
The thickness of the piezoelectric layer 2: about 400 nm
The length of the excitation region C (see FIG. 1B): about 40 μm
The number of electrode pairs of the electrode finger 3 and the electrode finger 4: 21 pairs
The center-to-center distance (pitch) between the electrode finger 3 and the electrode finger 4: about 3 μm
The width of the electrode finger 3 and the electrode finger 4: about 500 nm
d/p: about 0.133
The intermediate layer 7: about 1-μm thick silicon oxide film

The support substrate 8: Si

The excitation region C (see FIG. 1B) is a region where the electrode finger 3 and the electrode finger 4 overlap when viewed in the X-direction orthogonal or substantially orthogonal to the lengthwise direction of the electrode finger 3 and the electrode finger 4. The length of the excitation region C is a dimension measured in the lengthwise direction of the electrode finger 3 and the electrode finger 4 in the excitation region C. The excitation region C is an example of the “intersecting region”.

In the first example embodiment, the electrode-to-electrode distance of an electrode pair of the electrode finger 3 and the electrode finger 4 is equal or substantially equal among all the plurality of pairs. In other words, the electrode fingers 3 and the electrode fingers 4 are arranged at an equal or substantially equal pitch.

As is apparent in FIG. 5, although reflectors are not provided, a fractional bandwidth is about 12.5%, and good resonance characteristics are obtained.

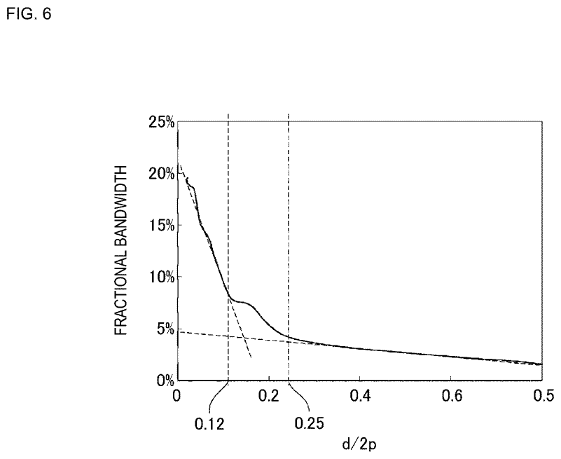

In the first example embodiment, d/p is, for example, about 0.5 or less or more preferably about 0.24 or less when d is the thickness of the piezoelectric layer 2 and p is the center-to-center distance between electrodes of the electrode finger 3 and the electrode finger 4. This point is described with reference to FIG. 6.

A plurality of acoustic wave devices were obtained similarly to the acoustic wave device that achieved the resonance characteristics illustrated in FIG. 5, but with different values of d/2p. FIG. 6 is an explanatory diagram illustrating the relation between d/2p and a fractional bandwidth as a resonator in the acoustic wave device of the first example embodiment when p is the center-to-center distance of adjacent electrodes or the average distance of the center-to-center distances and d is the average thickness of the piezoelectric layer 2.

As illustrated in FIG. 6, when d/2p exceeds about 0.25, i.e., when d/p>about 0.5, the fractional bandwidth is less than about 5% despite the adjustment of d/p. In contrast, when d/2p about 0.25, i.e., when d/p about 0.5, the fractional bandwidth can be brought to about 5% or more when d/p is changed within that range, and thus, a resonator having a high coupling coefficient can be provided. Also, when d/2p is, for example, about 0.12 or less, i.e., when d/p is about 0.24 or less, the fractional bandwidth can be increased to about 7% or more. In addition, adjusting d/p within this range makes it possible to obtain a resonator with an even wider fractional bandwidth and therefore achieve a resonator having an even higher coupling coefficient. This shows that when d/p is about 0.5 or less, a resonator utilizing bulk waves of the first-order thickness-shear mode and having a high coupling coefficient may be provided.

The at least one electrode pair may be a single pair, and when there is a single pair of electrodes, p described above is the center-to-center distance between the electrode finger 3 and the electrode finger 4 adjacent to each other. Also, in a case where there are 1.5 electrode pairs or more, p is the average distance of the center-to-center distances of respective adjacent electrode fingers of the electrode finger 3 and the electrode finger 4.

Regarding the thickness d of the piezoelectric layer 2, if the piezoelectric layer 2 has uneven thickness, the average value of the thickness may be used.

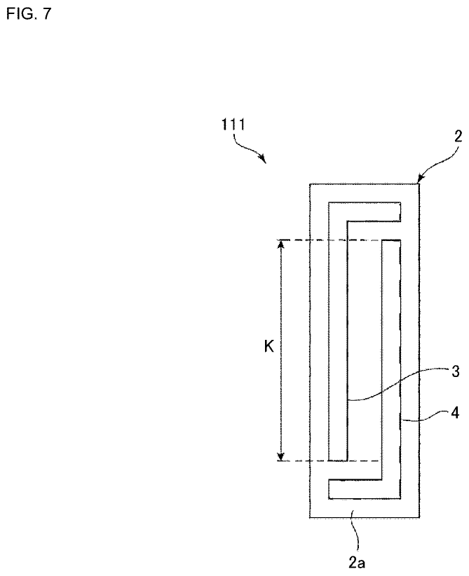

FIG. 7 is a plan view illustrating an example where a single pair of electrodes is provided in the acoustic wave device of the first example embodiment. In an acoustic wave device 111, a single electrode pair including the electrode finger 3 and the electrode finger 4 is provided on the first main surface 2a of the piezoelectric layer 2. K in FIG. 7 is an intersecting width. As described earlier, the acoustic wave device of example embodiments of the present invention may include a single pair of electrodes. In this case as well, bulk waves of the first-order thickness-shear mode can be effectively excited if d/p described above is, for example, about 0.5 or less.

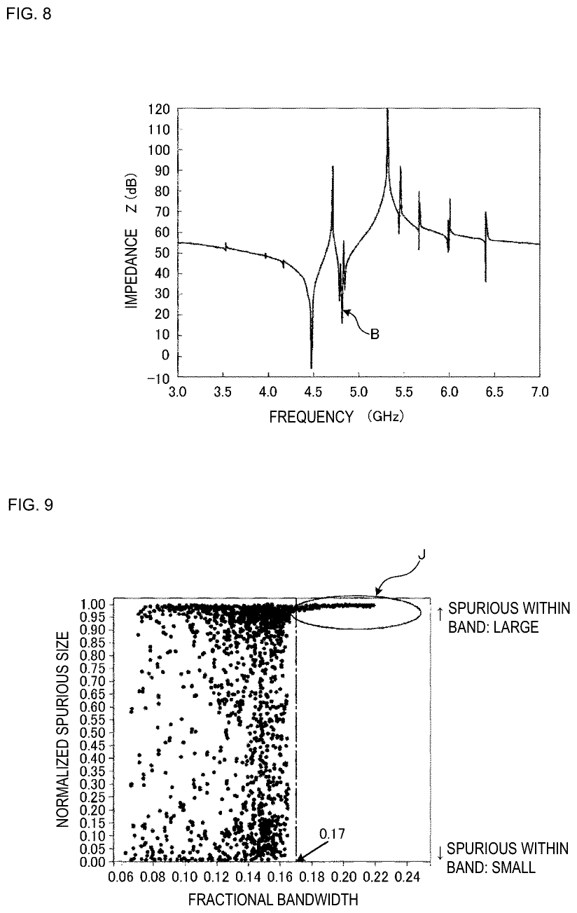

Preferably, the acoustic wave device 1 satisfies MR about 1.75(d/p)+0.075 where MR is the metallization ratio of any adjacent electrode fingers of the plurality of electrode fingers 3 and the plurality of electrode fingers 4 to the excitation region C which is a region where the electrode finger 3 and the electrode finger 4 adjacent to each other overlap when viewed in a direction in which the electrode finger 3 and the electrode finger 4 face each other. In this case, a spurious emission can be effectively reduced. This point is described with reference to FIGS. 8 and 9.

FIG. 8 is a reference diagram illustrating an example of the resonance characteristics of the acoustic wave device of the first example embodiment. A spurious emission indicated with arrow B appears between the resonant frequency and the anti-resonant frequency. Note that d/p=about 0.08, and LiNbO₃ has Euler angles (0°, 0°, 90°). Also, the metallization ratio MR=about 0.35.

The metallization ratio MR is described with reference to FIG. 1B. In the electrode structure in FIG. 1B, with a single pair of the electrode finger 3 and the electrode finger 4 in focus, it is assumed that only this single pair of the electrode finger 3 and the electrode finger 4 is provided. In this case, a portion surrounded by the dot-dash line is the excitation region C. This excitation region C includes a region of the electrode finger 3 overlapping the electrode finger 4, a region of the electrode finger 4 overlapping the electrode finger 3, and a region where the electrode finger 3 and the electrode finger 4 overlap each other in a region between the electrode finger 3 and the electrode finger 4, when the electrode finger 3 and the electrode finger 4 are viewed in a direction orthogonal or substantially orthogonal to the lengthwise direction of the electrode finger 3 and the electrode finger 4, i.e., in a direction in which the electrode finger 3 and the electrode finger 4 face each other. The area of the electrode finger 3 and the electrode finger 4 within the excitation region C in relationship to the area of the excitation region C is the metallization ratio MR. In other words, the metallization ratio MR is the ratio of the area of the metallization portion to the area of the excitation region C.

In a case where a plurality of pairs of the electrode finger 3 and the electrode finger 4 are provided, MR is the proportion of the metallization portions included in the entire excitation region C to the total area of the excitation region C.

FIG. 9 is an explanatory diagram illustrating the relationship, in the acoustic wave device of the first example embodiment, between the fractional bandwidth in a case where a large number of acoustic wave resonators are configured and the amount of phase rotation of spurious impedance normalized by about 180° as a spurious size. The fractional bandwidth was adjusted by variously changing the film thickness of the piezoelectric layer 2 and the dimensions of the electrode fingers 3 and the electrode fingers 4. Also, although FIG. 9 illustrates results obtained in a case of using the piezoelectric layer 2 made of Z-cut LiNbO₃, the same or similar tendencies are observed in a case of using the piezoelectric layer 2 with other cut-angles.

In the region surrounded by the oval J in FIG. 9, the spurious emission is about 1.0, which is large. As is apparent in FIG. 9, when the fractional bandwidth exceeds about 0.17, i.e., exceeds about 17%, a spurious emission with a spurious level of about 1 or more appears in the pass band even if the parameters forming the fractional bandwidth are changed. In other words, similar to the resonance characteristics illustrated in FIG. 8, a large spurious emission indicated by the arrow B appears in the band. Thus, the fractional bandwidth is preferably, for example, about 17% or less. In this case, the spurious emission can be reduced by adjusting, for example, the film thickness of the piezoelectric layer 2 and the dimensions of the electrode fingers 3 and the electrode fingers 4.

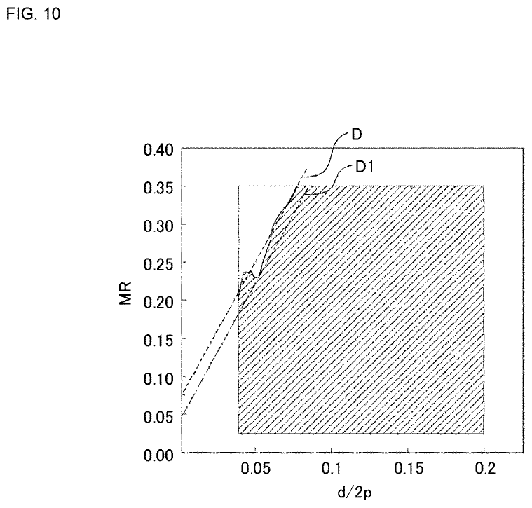

FIG. 10 is an explanatory diagram illustrating the relationship between d/2p, the metallization ratio MR, and the fractional bandwidth. As the acoustic wave device 1 of the first example embodiment, various acoustic wave devices 1 were provided with different values of d/2p and MR, and fractional bandwidths of the acoustic wave devices 1 were measured. The hatched portion on the right side of the broken line D in FIG. 10 is the region where the fractional bandwidth is about 17% or less. The border between the hatched region and a non-hatched region is expressed by MR=about 3.5(d/2p)+0.075. Thus, MR=about 1.75(d/p)+0.075. Therefore, preferably, for example, MR about 1.75(d/p)+0.075. This facilitates bringing the fractional bandwidth to about 17% or less. More preferable is the region on the right side of MR=about 3.5(d/2p)+0.05 indicated by the dot-dash line D1 in FIG. 10. Thus, if MR about 1.75(d/p)+0.05, the fractional bandwidth can be brought to about 17% or less with reliability.

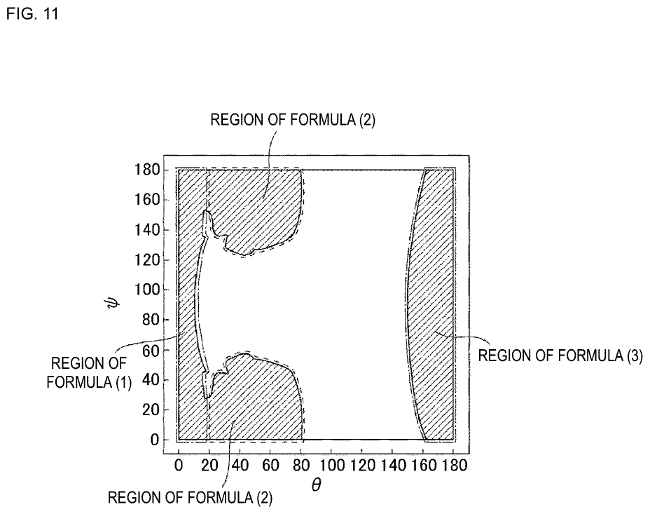

FIG. 11 is an explanatory diagram illustrating a map of the fractional bandwidth in relation to the Euler angles (0°, θ, ψ) of LiNbO₃ in a case where d/p is brought to almost zero. The hatched portions in FIG. 11 are regions where fractional bandwidths of at least 5% or more are obtained. Approximation of the ranges of the regions yields ranges expressed by Formulae (1), (2), and (3) below.

(0°±10°,0° to 20°,any given ψ) Formula (1)

(0°±10°,20° to 80°,0° to 60°(1−(θ−50)²/900)^{1/2}) or (0°±10°,20° to 80°,[180°−60°(1−(θ−50)²/900)^{1/2}] to 180°) Formula(2)

(0°±10°,[180°−30°(1−(ψ−90)²/8100)^{1/2}] to 180°, any given ψ) Formula (3)

Thus, the range of Euler angles of Formula (1), (2), or (3) is preferable because the fractional bandwidth can be sufficiently widened.

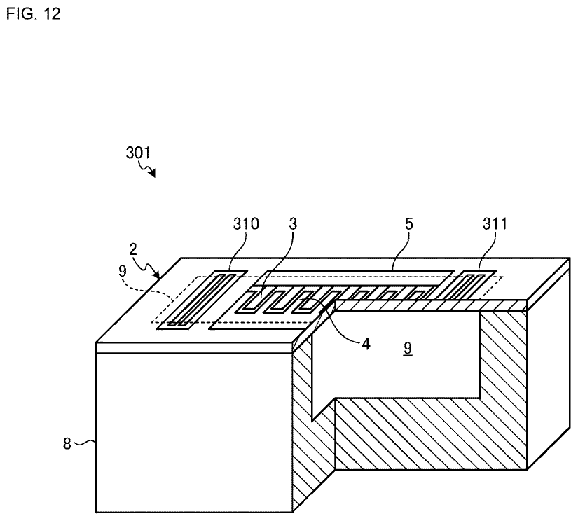

FIG. 12 is a partially cut-away perspective view illustrating an acoustic wave device according to an example embodiment of the present invention. In FIG. 12, the broken line denotes an outer periphery of the void portion 9. An acoustic wave device of an example embodiment of the present invention may use plate waves. In that case, as illustrated in FIG. 12, an acoustic wave device 301 includes reflectors 310, 311. The reflectors 310, 311 are provided on both sides of the electrode fingers 3, 4 on the piezoelectric layer 2 in the acoustic wave propagation direction. In the acoustic wave device 301, Lamb waves as plate waves are excited by application of an alternating current electric field to the electrode fingers 3, 4 above the void portion 9. Because the reflectors 310, 311 are provided on both sides, resonance characteristics can be obtained with the Lamb waves as plate waves.

As described above, in the acoustic wave devices 1, 101, bulk waves of the first-order thickness-shear mode are used. Also, in the acoustic wave devices 1, 101, the first electrode finger 3 and the second electrode finger 4 are adjacent electrodes, and d/p is set to be, for example, about 0.5 or less where d is the thickness of the piezoelectric layer 2 and p is the center-to-center distance between the first electrode finger 3 and the second electrode finger 4. Thus, the Q factor can be increased even if the acoustic wave device is reduced in size.

In the acoustic wave devices 1, 101, the piezoelectric layer 2 is made of, for example, lithium niobate or lithium tantalate. The first electrode fingers 3 and the second electrode fingers 4 facing each other in a direction intersecting the thickness direction of the piezoelectric layer 2 are on the first main surface 2a or the second main surface 2b of the piezoelectric layer 2, and it is preferable that the first electrode fingers 3 and the second electrode fingers 4 are covered by a protective film from above.

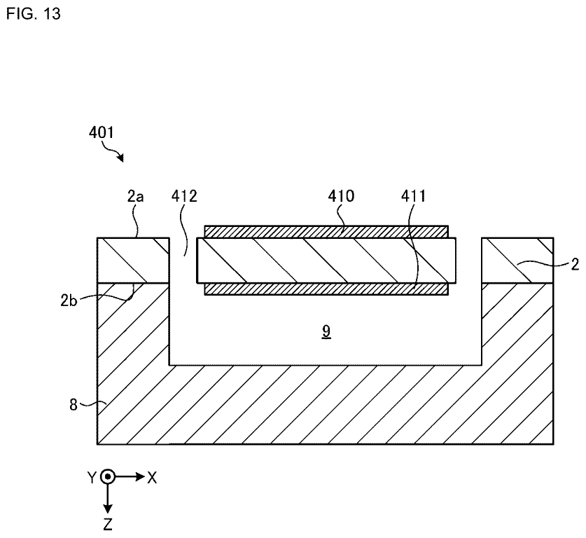

FIG. 13 is a sectional view illustrating an acoustic wave device according to an example embodiment of the present invention. The acoustic wave device may be a device that utilizes bulk waves as illustrated in FIG. 13, i.e., a BAW (Bulk Acoustic Wave) element. In this case, an acoustic wave device 401 includes functional electrodes 410, 411. The functional electrodes 410, 411 are provided on both sides of the piezoelectric layer 2 in the thickness direction. In the example in FIG. 13, the support substrate 8 includes the void portion 9 on the piezoelectric layer 2 side, and the functional electrode 411 is provided in the void portion 9.

In the example in FIG. 13, the piezoelectric layer 2 includes a through-hole 412. The through-hole 412 is a hole passing through the piezoelectric layer 2 in the Z-direction. The through-hole 412 communicates with the void portion 9. When the through-hole 412 is provided in the piezoelectric layer 2, an etching solution can be poured through the through-hole 412 after the piezoelectric layer 2 is bonded to the support substrate 8, so that a sacrificial layer provided at the void portion 9 prior to the bonding can be etched.

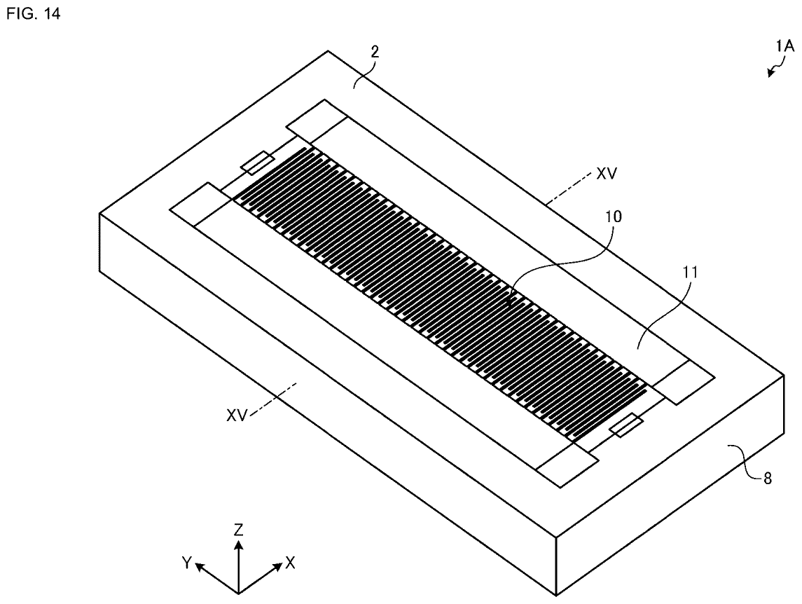

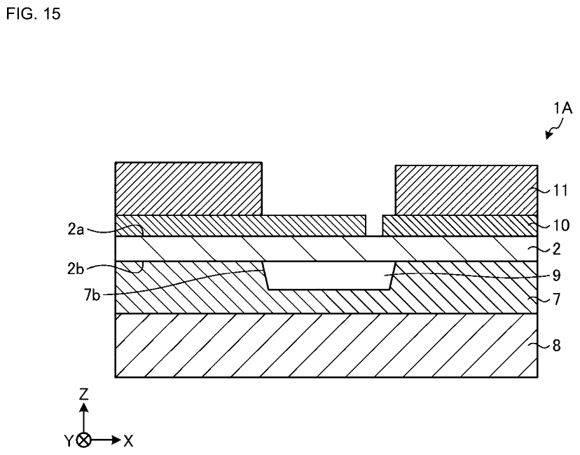

FIG. 14 is a perspective view illustrating an example of an acoustic wave device according to the first example embodiment. FIG. 15 is a sectional view taken along line XV-XV in FIG. 14. As illustrated in FIGS. 14 and 15, an acoustic wave device 1A according to the first example embodiment includes the support substrate 8, the intermediate layer 7, the piezoelectric layer 2, an IDT electrode 10, and a wiring electrode 11. The intermediate layer 7 includes the void portion 9 at a position where at least a portion thereof overlaps the IDT electrode 10 in plan view in the Z-direction. In the example in FIG. 15, the void portion 9 is provided on a surface of the intermediate layer 7 on the piezoelectric layer 2 side. The wiring electrode 11 is an electrode connecting the resonator including the IDT electrode 10 to other elements. Although the wiring electrode 11 is provided on the IDT electrode 10 in the example in FIGS. 14 and 15, this is merely an example. The following description may assume that one of the orientations parallel or substantially parallel to the Z-direction is up, and the other orientation is down. In the acoustic wave device 1A, the intermediate layer 7 is provided on the support substrate 8. Also, the piezoelectric layer 2 is provided on the intermediate layer 7.

The intermediate layer 7 includes an inner sidewall 7b. The inner sidewall 7b is, of a wall surface of the intermediate layer 7 exposed to the void portion 9, a wall surface which is a sidewall not parallel or substantially parallel to the XY-plane and extends in the Y-direction. The surface roughness (Ra) of the inner sidewall 7b is, for example, about 0.0055 μm or more. Consequently, a spurious emission in the pass band can be reduced. The surface roughness (Ra) of the inner sidewall 7b is preferably, for example, about 0.0143 μm or more. Consequently, a spurious emission in the pass band can be further reduced. Also, the surface roughness (Ra) of the inner sidewall 7b is, for example, approximately 3 μm or less. This facilitates manufacturing of the acoustic wave device 1A.

Ra of the inner sidewall 7b of the intermediate layer 7 is measured using, for example, a STEM (Scanning Transmission Electron Microscope) to obtain a STEM image of the vicinity of the Y-direction center of the inner sidewall 7b being observed in the X-direction. Ra of the inner sidewall 7b may also be measured based on, for example, an SEM (Scanning Electron Microscope) image obtained using an SEM.

### Test Examples

Test examples are described below. In the text examples of the acoustic wave device 1A according to the first example embodiment, simulation models were created using the following design parameters.
The piezoelectric layer 2: LiNbO₃ with Euler angles (0°, 37.5°, 0°)
The thickness of the piezoelectric layer 2: about 400 nm
The thickness of the electrode fingers 3 and the electrode fingers 4: about 500 nm
The center-to-center distance (pitch) between the electrode finger 3 and the electrode finger 4: about 3.75 μm
The width of the electrode fingers 3 and the electrode fingers 4 (the length in the Y-direction): about 1.013 μm
The width of the excitation region C: about 65 μm
The numbers of the electrode fingers 3 and the electrode fingers 4: 127
The intermediate layer 7: SiO₂
The thickness of the intermediate layer 7: about 1600 μm
The depth of the void portion 9 (the length in the Z-direction): about 1000 μm
The support substrate 8: Si

In the simulation, the impedance characteristics and the return loss were calculated for the following Test Examples 1 to 4 with different surface roughnesses (Ra) of the inner sidewall 7b.
Ra in Test Example 1: about 0.048 μm
Ra in Test Example 2: about 0.055 μm
Ra in Test Example 3: about 0.143 μm
Ra in Test Example 4: about 0.327 μm

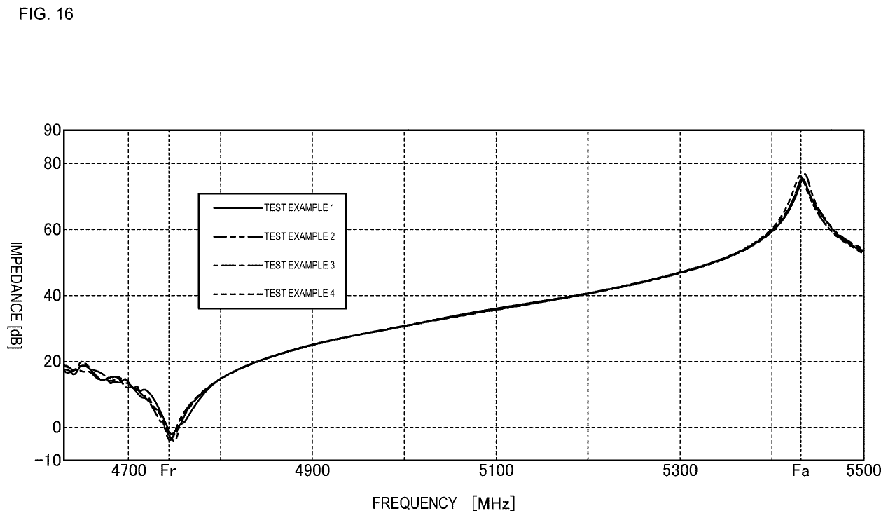

FIG. 16 is a diagram illustrating the impedance characteristics of the acoustic wave devices according to Test Examples 1 to 4. As illustrated in FIG. 16, in all of Test Examples 1 to 4, the resonant frequency (Fr) was approximately 4744 MHz, and the anti-resonant frequency (Fa) was approximately 5430 MHz.

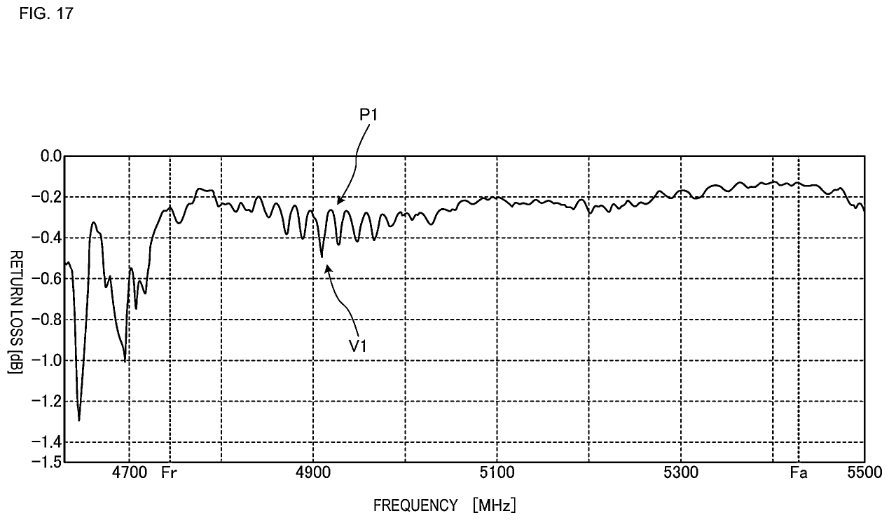

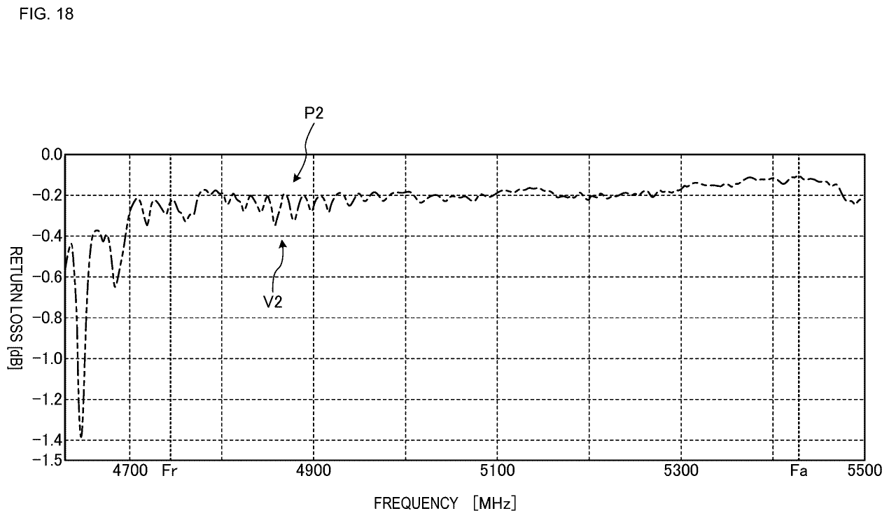

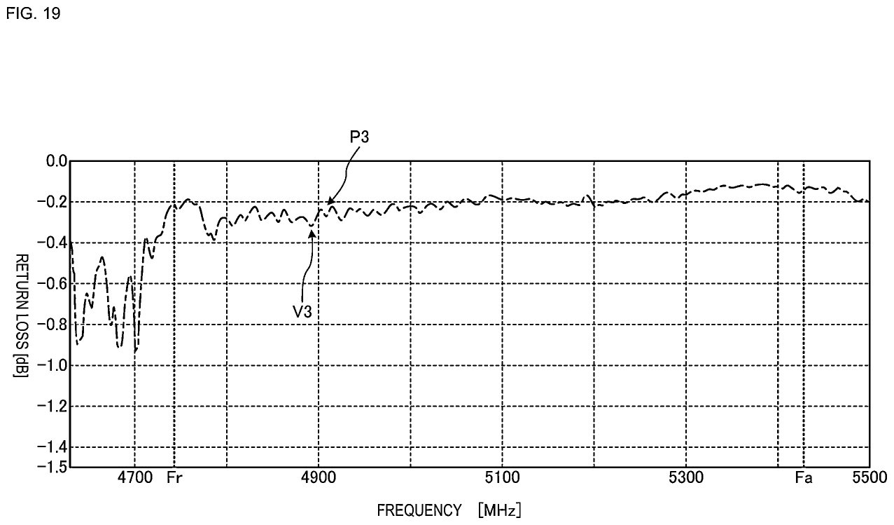

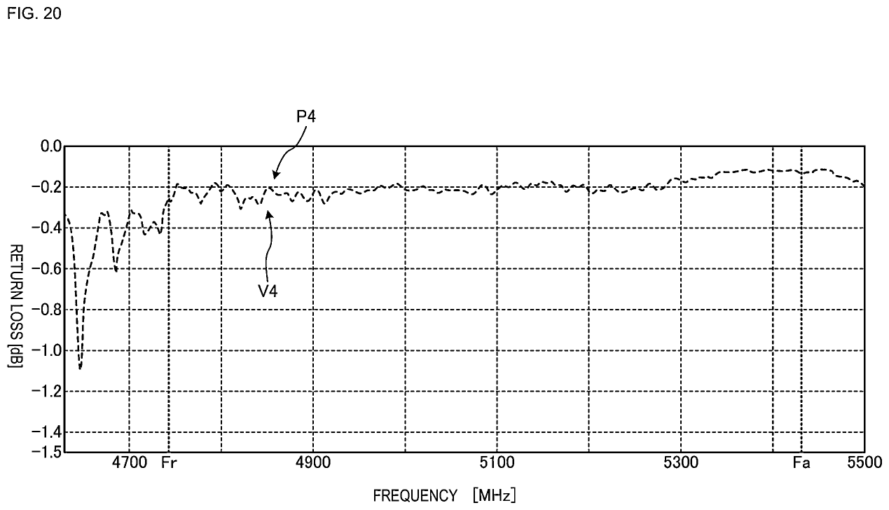

FIG. 17 is a diagram illustrating the return loss of the acoustic wave device according to Test Example 1. FIG. 18 is a diagram illustrating the return loss of the acoustic wave device according to Test Example 2. FIG. 19 is a diagram illustrating the return loss of the acoustic wave device according to Test Example 3. FIG. 20 is a diagram illustrating the return loss of the acoustic wave device according to Test Example 4. In the acoustic wave devices according to Test Examples 1 to 4, as illustrated in FIGS. 17 to 20, ripples occurred within the pass band (the band from Fr to Fa). Here, the ripples include ones attributable to reflection from the inner sidewall 7b and ones attributable to the electrode fingers 3, 4. In the simulation, through analysis, the ripples in the pass band were divided into ripples attributable to reflection from the inner sidewall 7b and ripples attributable to the electrode fingers 3, 4. In the acoustic wave devices according to Test Examples 1 to 4, ripples appearing at about 4900 MHz or higher are the ripples attributable to reflection from the inner sidewall 7b. In the following description, in FIGS. 17 to 20, in the ripples in the pass band and attributable to reflection from the inner sidewall 7b, with respect to one period of a ripple with the maximum amplitude, a local maximum location on the ripple is referred to as the peak of the ripple and a local minimum location on the ripple is referred to as the valley of the ripple. Thus, in FIGS. 17 to 20, the peak of a ripple is each location indicated by corresponding one of the arrows P1 to P4, and the valley of a ripple is the location indicated by the arrows V1 to V4, respectively.

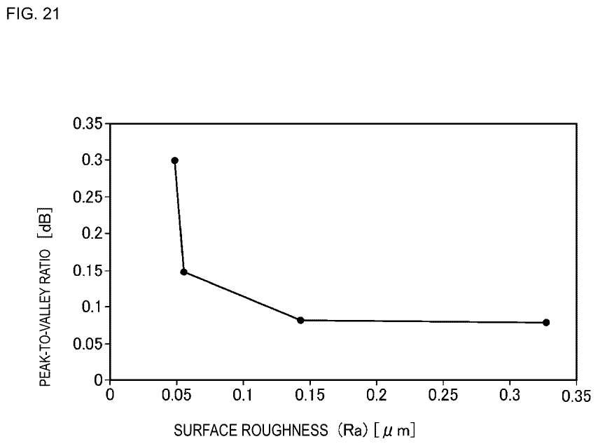

FIG. 21 is a diagram illustrating the peak-to-valley ratios of the ripples in the acoustic wave devices according to Test Examples 1 to 4. Table 1 is a table showing measurement results of the ripples in the acoustic wave devices according to Test Examples 1 to 4. In FIG. 21 and Table 1, the peak-to-valley ratio of a ripple is the value of the return loss at the valley of the ripple in relation to the value of the return loss at the peak of the ripple. As illustrated in FIG. 21 and Table 1, in the acoustic wave device according to Test Example 1 which is a comparative example, the peak-to-valley ratio of the ripple is large, and a spurious emission in the pass band is relatively large. Meanwhile, in the acoustic wave device according to Test Example 2 which is an example according to the present invention, compared to Test Example 1, the peak-to-valley ratio of the ripple is small, and a spurious emission in the pass band is small. Also, in the acoustic wave devices according to Test Examples 3 and 4 which are examples according to the present invention, compared to Test Example 2, the peak-to-valley ratio of the ripple is even smaller, and a spurious emission in the pass band is even smaller.

TABLE 1

| | | | | peak-to- |
|---|---|---|---|---|
| | Ra | peak | valley | valley ratio |
| Test Example | (μm) | (dB) | (dB) | (dB) |
| Test Example 1 | 0.048 | −0.268 | −0.497 | 0.299 |
| Test Example 2 | 0.055 | −0.2 | −0.348 | 0.148 |
| Test Example 3 | 0.143 | −0.236 | −0.318 | 0.082 |
| Test Example 4 | 0.327 | −0.207 | −0.286 | 0.079 |

As described above, the acoustic wave device 1A according to the first example embodiment includes the support substrate 8 with a thickness in the first direction, the intermediate layer 7 provided on the support substrate 8, the piezoelectric layer 2 provided on the intermediate layer 7, and the IDT electrode 10 including the first electrode finger 3 being provided at the piezoelectric layer 2 in the first direction and extending in the second direction intersecting the first direction, the first busbar electrode 5 to which the first electrode finger 3 is connected, the second electrode finger 4 facing the first electrode finger 3 in the third direction orthogonal or substantially orthogonal to the second direction and extending in the second direction, and the second busbar electrode 6 to which the second electrode finger 4 is connected. The intermediate layer 7 includes the void portion 9 at a position where the void portion 9 at least partially overlaps the IDT electrode 10 in plan view, and the surface roughness (Ra) of the inner sidewall 7b of the intermediate layer 7 is, for example, about 0.0055 μm or more. This enables a reduction in ripples in the acoustic wave device and thus enables reduction in a spurious emission in the pass band.

In a preferable mode, the surface roughness (Ra) of the inner sidewall 7b of the intermediate layer 7 is, for example, about 0.0143 μm or more. This enables further reduction in ripples in the acoustic wave device and thus enables further reduction in a spurious emission in the pass band.

In a preferable structure, the surface roughness (Ra) of the inner sidewall 7b of the intermediate layer 7 is, for example, about 0.0327 μm or less. This enables reduction in the spurious emission in the pass band.

In a preferable structure, the thickness of the piezoelectric layer 2 is 2p or less where p is the center-to-center distance between the first electrode finger 3 and the second electrode finger 4 adjacent to each other. This enables device size reduction of the acoustic wave device 1 and also increase of the Q factor.

In a preferable structure, the piezoelectric layer 2 includes lithium niobate or lithium tantalate. This makes it possible to provide an acoustic wave device with which good resonance characteristics can be obtained.

In a preferable structure, the acoustic wave device is structured to be able to utilize bulk waves of a thickness-shear mode. This makes it possible to provide an acoustic wave device which has a large coupling coefficient and with which good resonance characteristics can be obtained.

Further in a preferable mode, d/p is, for example, about 0.24 or less where d is the thickness of the piezoelectric layer 2 and p is the center-to-center distance between the first electrode finger 3 and the second electrode finger 4 adjacent to each other. This enables the size of the acoustic wave device 1 to be reduced and also increase of the Q factor.

In a preferable structure, a region where the first electrode finger 3 and the second electrode finger 4 overlap each other when viewed in the third direction is the excitation region C, and MR about 1.75(d/p)+0.075, where MR is the metallization ratio of the first electrode finger 3 and the second electrode finger 4 to the excitation region C. In this case, the fractional bandwidth can be brought to about 17% or less with reliability.

In a preferable structure, the acoustic wave device is structured to utilize plate waves. This makes it possible to provide an acoustic wave device with which good resonance characteristics can be obtained.

In a preferable structure, the Euler angles (φ, θ, ψ) of the lithium niobate or the lithium tantalate are within the ranges of Formula (1), (2), or (3) below. In this case, the fractional bandwidth can be widened sufficiently.

(0°±10°,0° to 20°,any given ψ) Formula (1)

(0°±10°,20° to 80°,0° to 60°(1−(θ−50)²/900)^{1/2}) or (0°±10°,20° to 80°,[180°−60°(1−(θ−50)²/900)^{1/2}] to 180°) Formula(2)

(0°±10°,[180°−30°(1−(ψ−90)²/8100)^{1/2}] to 180°, any given ψ) Formula (3)

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a support substrate with a thickness in a first direction;
an intermediate layer on the support substrate;
a piezoelectric layer on the intermediate layer; and
an IDT electrode including a first electrode finger at the piezoelectric layer in the first direction and extending in a second direction intersecting the first direction, a first busbar electrode to which the first electrode finger is connected, a second electrode finger facing the first electrode finger in a third direction orthogonal or substantially orthogonal to the second direction and extending in the second direction, and a second busbar electrode to which the second electrode finger is connected; wherein
the intermediate layer includes a void portion at least partially overlapping the IDT electrode in plan view; and
a surface roughness of an inner sidewall of the intermediate layer is about 0.0055 μm or more.

2. The acoustic wave device according to claim 1, wherein the surface roughness of the inner sidewall of the intermediate layer is about 0.0143 μm or more.

3. The acoustic wave device according to claim 1, wherein the surface roughness of the inner sidewall of the intermediate layer is about 0.0327 μm or less.

4. The acoustic wave device according to claim 1, wherein a thickness of the piezoelectric layer is 2p or less where p is a center-to-center distance between the first electrode finger and the second electrode finger adjacent to each other.

5. The acoustic wave device according to claim 1, wherein the piezoelectric layer includes lithium niobate or lithium tantalate.

6. The acoustic wave device according to claim 5, wherein the acoustic wave device is structured to generate a bulk wave of a thickness-shear mode.

7. The acoustic wave device according to claim 6, wherein d/p≤about 0.5, where d is a thickness of the piezoelectric layer and p is a center-to-center distance between the first electrode finger and the second electrode finger adjacent to each other.

8. The acoustic wave device according to claim 7, wherein d/p is about 0.24 or less.

9. The acoustic wave device according to claim 1, wherein
a region where the first electrode finger and the second electrode finger overlap each other when viewed in the third direction is an excitation region; and
MR≤about 1.75(d/p)+0.075, where MR is a metallization ratio of the first electrode finger and the second electrode finger to the excitation region.

10. The acoustic wave device according to claim 1, wherein the acoustic wave device is structured to generate a plate wave.

11. The acoustic wave device according to claim 5, wherein Euler angles (φ, θ, ψ) of the lithium niobate or the lithium tantalate are within ranges of Formula (1), (2), or (3) below:
(0°±10°,0° to 20°,any given ψ) Formula (1);
(0°±10°,20° to 80°,0° to 60°(1−(θ−50)²/900)^{1/2}) or (0°±10°,20° to 80°,[180°−60°(1−(θ−50)²/900)^{1/2}] to 180°) Formula(2); and
(0°±10°,[180°−30°(1−(ψ−90)²/8100)^{1/2}] to 180°, any given ψ) Formula (3).

12. The acoustic wave device according to claim 1, wherein the piezoelectric layer includes lithium niobate.

13. The acoustic wave device according to claim 1, wherein the piezoelectric layer includes lithium tantalate.

14. The acoustic wave device according to claim 1, wherein a thickness of the piezoelectric layer is about 50 nm or more and about 1000 nm or less.

15. The acoustic wave device according to claim 1, wherein each of the first and second electrode fingers has a rectangular or substantially rectangular shape.

16. The acoustic wave device according to claim 1, wherein a center-to-center distance between the first and second electrode fingers is in a range from about 1 μm or more to about 10 μm or less.

17. The acoustic wave device according to claim 1, wherein the intermediate layer includes silicon oxide.

18. The acoustic wave device according to claim 1, wherein the support substrate includes Si.

19. The acoustic wave device according to claim 18, wherein a resistivity of the Si is about 4 kΩ or more.

20. The acoustic wave device according to claim 1, wherein each of the first and second electrode fingers includes Al or an AlCu alloy.
